(19) United States
(12) Patent Application Publication
(10) Pub. No.: US 2026/0330081 A1
(43) Pub. Date: Oct. 22, 2026

(54) Framework for Navigating Modeling

(71) Applicant: The Charles Stark Draper Laboratory, Inc., Cambridge, MA (US)

(72) Inventors: Eric Schulken, Cambridge, MA (US); Matthew Bouhall, Cambridge, MA (US)

(21) Appl. No.: 19/648,136

(22) Filed: Apr. 15, 2026

Related U.S. Application Data
(60) Provisional application No. 63/731,745, filed on Apr. 16, 2025.

(51) Int. Cl. G06F 30/15

(52) U.S. Cl. CPC G06F 30/15

(57) ABSTRACT

A system for simulation includes an input processor and a simulation module. The input processor is configured to receive user input specifying one or more simulation parameters in a user-specified format, access a model-specific plugin associated with a simulation model, the plugin defining translation logic for converting simulation parameters from the user-specified format to a model-compatible format required by the simulation model, and generate one or more simulation batches including applying the translation logic of the plugin to convert the user input into the model-compatible format. The simulation module is configured to execute the one or more simulation batches using the simulation model to generate simulation results.

### CROSS-REFERENCES TO RELATED APPLICATIONS

This application claims the benefit of U.S. Provisional Application No. 63/731,745 filed Apr. 16, 2025, the entire contents of which are hereby incorporated herein by reference.

### TECHNICAL FIELD

Aspects of the disclosure generally relate to systems and methods for a robust framework to simulate navigation.

### BACKGROUND

Various simulation programs exist to model navigation, guidance, and control systems. In complex simulation environments, it can be difficult to accurately account for all simulation variables.

### SUMMARY

Presented herein are systems and methods for advanced vehicle simulations. The system can agnosticize a plurality of complex inputs for performance of simulations to reduce error, computation time, and provides for generation of complex Monte Carlo permutations with a variety of perturbations to the input data.

At least one aspect of the present disclosure is directed to a system for flight simulations. The system can include a framework. The framework can communicate with one or more simulators. The framework can include one or more inputs including a desired output. The framework can include one or more models. At least one of the models can generate a first set of parameters for at least one of the simulators based on the inputs and the at least one simulator. The framework can generate a second set of parameters based on the first set of parameters and the at least one simulator to provide to the at least one simulator according to a sequence determined by the desired output.

At least one aspect of the present disclosure is directed towards a method for flight simulation. The method can include providing, by a simulation framework, one or more inputs to a set of models. The method can include generating, by a first model of the set of models, a first set of simulation parameters from the one or more inputs. The method can include determining, by the simulation framework, that at least a subset of the first set of simulation parameters does not conform to a simulation style. The method can include modifying, by the simulation framework, the subset to conform to the simulation style.

In a general aspect, a system for simulation includes an input processor and a simulation module. The input processor is configured to receive user input specifying one or more simulation parameters in a user-specified format, access a model-specific plugin associated with a simulation model, the plugin defining translation logic for converting simulation parameters from the user-specified format to a model-compatible format required by the simulation model, and generate one or more simulation batches including applying the translation logic of the plugin to convert the user input into the model-compatible format. The simulation module is configured to execute the one or more simulation batches using the simulation model to generate simulation results.

Aspects may include one or more of the following features.

The input processor may be further configured to access a number of model-specific plugins, each associated with a respective simulation model, and select the plugin corresponding to a simulation model specified in the user input.

The translation logic may include a coordinate frame transformation configured to convert one or more simulation parameters from a user-specified coordinate frame to a coordinate frame required by the simulation model. The coordinate frame transformation may be configured to convert a user-specified position from latitude, longitude, and altitude coordinates to Earth-Centered Inertial coordinates. The coordinate frame transformation may also be configured to convert a user-specified velocity from Mach number and flight path angle to an Earth-Centered Inertial velocity vector.

The input processor may be further configured to receive a run matrix defining a number of cases, each case representing a variation of one or more simulation parameters, and generate a number of simulation batches corresponding to the cases. The input processor may be further configured to receive sweep variables each defining a set of discrete values for a respective simulation parameter, and automatically expand the run matrix to include one case for each combination of sweep variable values.

The batch simulation module may include a model configuration module configured to apply a model configuration once per simulation batch before iterating over any cases defined in the user input, such that a change in model configuration defines a boundary between simulation batches. The batch simulation module may further include a repetition module configured to execute the simulation model for each of a number of repetitions defined by a Monte Carlo configuration specified in the user input, each repetition applying a random perturbation to one or more simulation parameters. The input processor may be further configured to apply the random perturbations to the user-specified values before applying the coordinate frame transformation defined by the plugin, such that the perturbations are applied in the user-specified coordinate frame. The batch simulation module may further include a matrix repetition module configured to iterate over a number of run matrix cases, where the repetition module is nested within the matrix repetition module such that each run matrix case is executed for the full number of repetitions before the next run matrix case begins.

The batch simulation module may further include a simulation instantiation module configured to instantiate a number of simulation runs for parallel execution. The batch simulation module may be further configured to clear simulation data from memory after completing a simulation batch and before beginning a subsequent simulation batch.

The input processor may be further configured to form a simulation data object including the user input and the model-compatible format parameters that is passed through an execution pipeline of the system. The batch simulation module may be further configured to receive one or more stop conditions each defining at least one of an upper bound or a lower bound on a monitored simulation quantity, and terminate a simulation run when the monitored quantity satisfies the stop condition.

The system may further include a user interface configured to receive the user input and produce a configuration file, where the input processor is configured to read the configuration file to generate the one or more simulation batches. The system may further include an output processor configured to aggregate simulation outputs across a number of simulation runs and compute one or more measures of effectiveness from the aggregated outputs. The batch simulation module may be further configured to select a vehicle dynamics model at a fidelity level specified in the user input, the fidelity level selected from a number of fidelity levels including at least a three-degrees-of-freedom model and a six-degrees-of-freedom model.

In another general aspect, a method for simulation includes receiving user input specifying one or more simulation parameters in a user-specified format, accessing a model-specific plugin defining translation logic for converting the simulation parameters to a model-compatible format required by a simulation model, generating one or more simulation batches including applying the translation logic to convert the user input into the model-compatible format, and executing the one or more simulation batches using the simulation model to generate simulation results.

In another general aspect, a non-transitory computer-readable medium stores instructions that, when executed by one or more processors, cause the processors to receive user input specifying one or more simulation parameters in a user-specified format, access a model-specific plugin defining translation logic for converting the simulation parameters to a model-compatible format required by a simulation model, generate one or more simulation batches including applying the translation logic to convert the user input into the model-compatible format, and execute the one or more simulation batches using the simulation model to generate simulation results.

Aspects may have one or more of the following advantages.

Among other advantages, aspects of the modeling and simulation framework described herein enable a user to efficiently configure and execute multi-configuration, multi-scenario simulation studies with higher-fidelity, modular GNC simulation capability, as compared to conventional systems such as AFSIM and STK. Conventional mission-level simulation tools such as AFSIM provide flexibility for concept analysis across multiple candidate approaches and mission scenarios, but often rely on relatively low-fidelity built-in models. The modeling and simulation framework described herein provides the concept-analysis flexibility of tools like AFSIM while supporting higher-fidelity, modular GNC and vehicle models that can be swapped and reconfigured without modifying the underlying framework. In addition, because the input processor handles coordinate frame transformations, parameter formatting, and input ordering dependencies automatically through model-specific plugins, users are not required to develop and maintain a bespoke cascade of transformation scripts each time a new model or simulation study is introduced, as is required with conventional approaches.

Aspects of the modeling and simulation framework described herein may advantageously enable a user to add support for a new simulation model by writing a single plugin that conforms to a defined interface, as compared to conventional approaches in which integrating a new model requires modifying the core simulation infrastructure and rewriting model-specific transformation logic from scratch for each new application.

Aspects of the modeling and simulation framework described herein may advantageously ensure that Monte Carlo perturbations are applied to user-specified values before coordinate frame transformations are performed, as compared to conventional approaches in which the sequencing of perturbation and transformation scripts must be managed manually by the user, creating brittle dependencies that are prone to error and can produce simulation outputs that do not reflect the intended perturbation.

Aspects of the modeling and simulation framework described herein may advantageously allow a user to specify a single set of inputs that is automatically expanded into a complete set of simulation batches, run matrix cases, and Monte Carlo repetitions, as compared to conventional approaches in which the entirety of the inputs must be re-entered for each comparative scenario, increasing the risk of error and inconsistency across runs.

Aspects of the modeling and simulation framework described herein may advantageously execute all simulation runs within a batch in parallel and automatically clear memory between batches, as compared to conventional approaches that require manual management of computational resources and do not provide built-in support for large multi-batch studies.

Aspects of the modeling and simulation framework described herein may advantageously allow a user to define simulation inputs in human-readable form, such as position in latitude, longitude, and altitude coordinates, while the framework automatically translates those inputs into the coordinate frames required by the selected simulation model, as compared to conventional approaches in which the user must understand and manually apply the internal coordinate frame requirements of each model.

Aspects of the modeling and simulation framework described herein may advantageously allow simulation study configurations to be saved to a configuration file and reproduced exactly or shared with other users, as compared to conventional approaches in which study setups are encoded in ad hoc scripts that are difficult to reproduce, version, or transfer across users and environments.

The systems and methods described herein are directed to a specific technical improvement in simulation software architecture and are not directed to an abstract idea. The modeling and simulation framework described herein solves a specific technical problem arising in the field of computational simulation: namely, that simulation inputs specified in human-readable form are not directly compatible with the internal data formats and coordinate frame requirements of simulation models, and that the sequencing of coordinate frame transformations relative to Monte Carlo perturbations produces incorrect simulation outputs if not managed correctly. These are concrete technical problems arising from the architecture of simulation software systems, not problems of human cognition or organization.

The solution implemented by the modeling and simulation framework is likewise technical in nature. The input processor applies model-specific plugins to translate and condition simulation inputs into formats compatible with each selected model, resolves coordinate frame transformation dependencies by enforcing a defined ordering of perturbation and transformation operations, and encapsulates all simulation inputs in a structured simulation data object that passes through the execution pipeline without requiring manual reformatting. The batch simulation module executes nested iteration over model configurations, run matrix cases, and Monte Carlo repetitions, instantiates simulation runs for parallel execution, and manages memory between batches. These operations are performed by specific software components operating on specific data structures in a defined sequence and produce a technical result (correctly conditioned simulation inputs and correctly ordered simulation outputs) that could not be achieved by mental processes or by conventional simulation tools.

The claimed systems and methods are thus rooted in computer technology and address a technical problem with a technical solution. The advantages described herein, including correct perturbation ordering, automatic coordinate frame translation, parallel batch execution, and plugin-based extensibility, are improvements to the functioning of the simulation software system itself, not merely improvements in the results produced by running a simulation.

### BRIEF DESCRIPTION OF THE DRAWINGS

The foregoing and other objects, aspects, features, and advantages of the disclosure will become more apparent and better understood by referring to the following description taken in conjunction with the accompanying drawings. The accompanying drawings are not intended to be drawn to scale. Like reference numbers and designations in the various drawings indicate like elements. For purposes of clarity, not every component may be labeled in every drawing. In the drawings:

FIG. 1 is a mission problem.

FIG. 2 is a modeling and simulation framework.

FIG. 3 is an input processor.

FIG. 4 is a run matrix.

FIG. 5 is a batch simulation module.

FIG. 6 is a pseudocode listing for the simulation framework’s batch simulation process.

FIG. 7 is a trajectory comparison.

FIG. 8 shows navigation error results.

FIG. 9 is an accuracy analysis.

FIG. 10 illustrates a diagram of a system for flight simulations.

FIG. 11 illustrates a method flow of the system for flight simulations.

### DETAILED DESCRIPTION

### 1. OVERVIEW

Reference will now be made to the embodiments illustrated in the drawings, and specific language will be used here to describe the same. It will nevertheless be understood that no limitation of the scope of the disclosure is thereby intended. Alterations and further modifications of the features illustrated here, and additional applications of the principles as illustrated here, which would occur to a person skilled in the relevant art and having possession of this disclosure, are to be considered within the scope of the disclosure.

Conventional guidance, navigation, and control (GNC) simulation programs lack robust modularity which would allow for preservation of various simulation model characteristics. Without this modularity and preservation, conventional systems rely on tedious repetitive input of information across various configurations. Conventional systems are not able to provide robust and standardized comparative simulations for a variety of input conditions.

While some conventional programs may provide the ability to define various inputs, these systems cannot always perform with the level of complexity needed, such as various changing model parameters surrounding sensors, GNC, and dynamics of a vehicle. For example, a potential trajectory of a vehicle can be affected by at least sensors on board the vehicle, navigator design, vehicle dynamics, the environment, other objects within the environment, etc. Modeling each of these effects is computationally difficult. Further, it is desirable to compare various potential trajectories of a vehicle based on various changing parameters. Examples of these parameters can include in-flight target updates, a loss of GPS or other navigating signal, reactions to unpredicted threats, or closure of a homing loop, among others. Conventional software cannot account for all of the various dependencies associated with a dependencies of the inputs to the simulation needed for complex analysis. With conventional programs, the entirety of the inputs, in addition to any perturbations, must be entered for each comparative scenario. This can introduce error and latency in generating inputs to the simulation.

Further, though some conventional programs can take in the inputs, inputs from various other programs may not be digestible by the main simulation program. In defining various inputs, they may not be suitable for a specific program, due to expected data forms or other limitations of the program. Oftentimes, various discrete simulations need be run in order to obtain the desired simulation output.

To address these and other technical problems, it is desirable to provide a framework to enable various model configurations and analysis setups for evaluation of various trajectories of vehicles. In some cases, various complex trajectories, orbits, and other movements under various conditions are desirable for modeling, to ascertain which guidance, navigation, and control (GNC) procedure would be optimal for a given situation.

Among other features, the systems and methods disclosed herein provide a framework to agnosticize inputs to one or more simulation programs. The framework can take in various variables, such as defined from other program, by a user, etc. and can perform discrete translation for each input not aligned with a particular simulation program. This offers the advantage of a more streamlined simulation and reducing runtime complexities, while ensuring appropriate simulation iteration. The systems and methods described herein can provide vehicle dynamics and guidance, navigation, and control (GNC) system simulations within a modular architecture and selectable model fidelity.

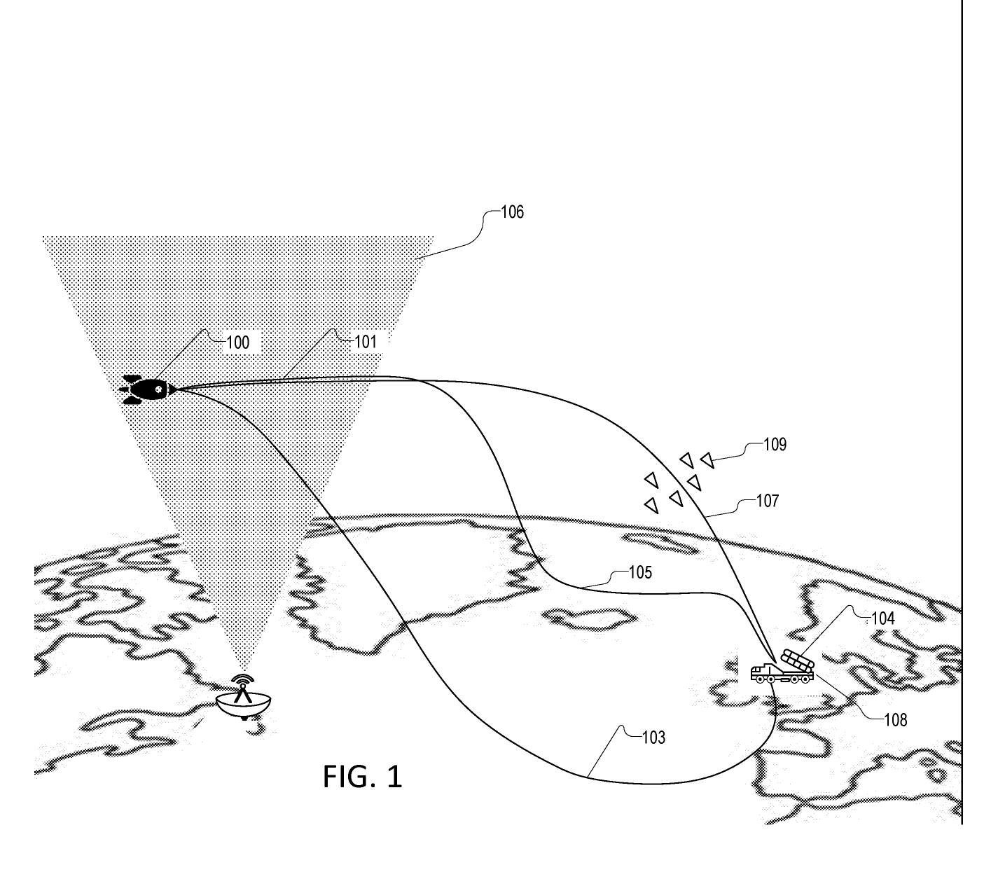

Referring to FIG. 1, in an example of a mission problem, a vehicle 100, such as a hypersonic boost-glide missile, traverses a path toward a target 104. The vehicle’s mission includes traversing and penetrating a contested environment that includes GPS jamming coverage 106 and Integrated Air and Missile Defense (IAMD) threats 108, where IAMD refers to networked air defense systems capable of detecting, tracking, and intercepting airborne threats.

In the example mission problem, there are four candidate approaches by which the vehicle 100 may reach the target 104. In a first approach 101, referred to as "out-navigate," the vehicle 100 traverses through the GPS-denied region using alternative navigation methods, such as celestial navigation (e.g., star tracking), dead reckoning, or inertial navigation. In a second approach 103, referred to as "avoid," the vehicle 100 takes a longer flight path that routes around the IAMD threats 108 and GPS jamming coverage 106. In a third approach 105, referred to as "out-maneuver," the vehicle 100 penetrates the IAMD threat 108 using evasive maneuvers. In a fourth approach 107, referred to as "confound," the vehicle 100 penetrates the IAMD threat 108 using countermeasures 109 (e.g., electronic countermeasures, decoys, chaff, or infrared countermeasures).

Determining which approach, or combination of approaches, is most likely to result in a successful strike on the target 104 includes evaluating the coupled effects of vehicle dynamics, guidance, navigation, and the contested environment across many candidate configurations and mission scenarios. Very generally, aspects described herein relate to a modeling and simulation framework that enables a user to efficiently set up and execute such multi-configuration, multi-scenario simulation studies, comparing the performance of candidate GNC architectures across varying mission conditions, as is described in greater detail below.

### 2. MODELING AND SIMULATION FRAMEWORK

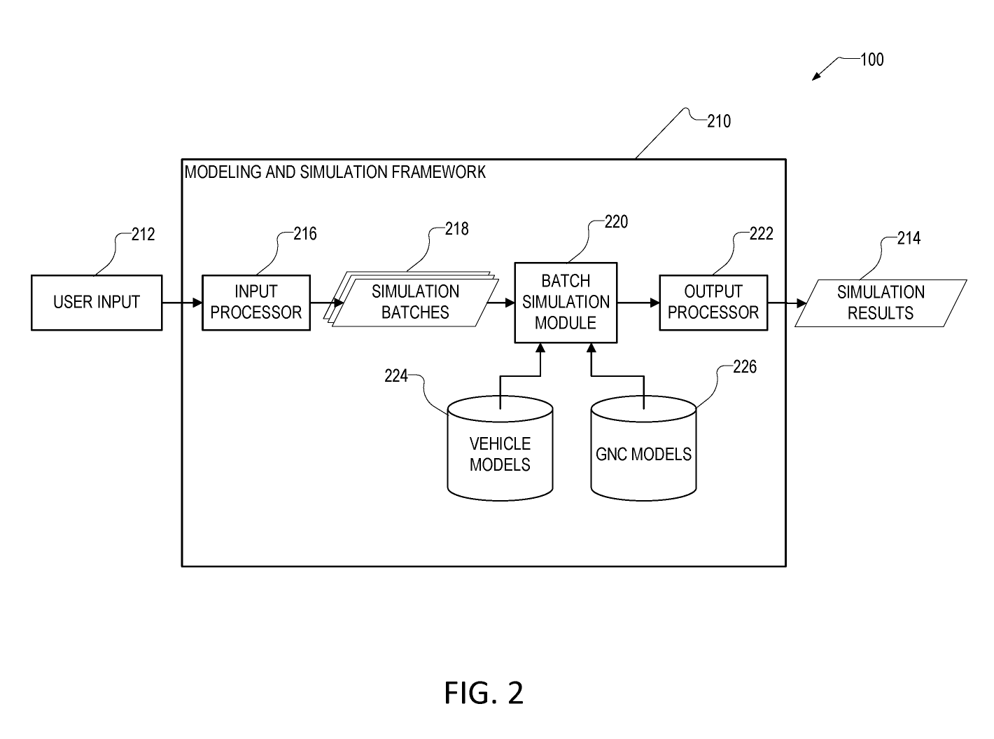

Referring to FIG. 2, in one example a modeling and simulation framework 210 receives user input 212 and processes the user input 212 to generate simulation results 214. As is described in greater detail below, in some examples, the user input 212 includes a nominal configuration, which specifies the model configuration, mission definition, and parameter tuning values that define a baseline simulation scenario. The user input 212 may also include a Monte Carlo configuration, which specifies the number of repetitions, the inputs to be randomized, and the degree of stochasticity to be applied. The user input 212 also includes a run matrix that defines a set of cases, each case representing a variation of any of the foregoing inputs, so that multiple configurations and scenarios may be evaluated in a single study. The modeling and simulation framework 210 includes an input processor 216, a batch simulation module 220, and an output processor 222.

The input processor 216 receives the user input 212 and processes it to generate one or more simulation batches 218. In general, the input processor 216 translates and conditions the user input 212 into a format suitable for use by the batch simulation module 220, including resolving coordinate frame transformations, formatting parameter values for compatibility with the simulation models, and applying any model-specific processing required by the selected configuration. The manner in which the input processor 216 performs this processing is described in greater detail below.

The simulation batches 218 are received by the batch simulation module 220, which executes the simulations defined by each batch. The batch simulation module 220 draws on a library of vehicle models 224 and a library of GNC models 226 to instantiate and run the simulations specified by each batch. The vehicle models 224 include physics-based models of vehicle flight dynamics, such as three-degrees-of-freedom (3DOF) and six-degrees-of-freedom (6DOF) models. The GNC models 226 include models of guidance algorithms, navigation systems, and control systems. The batch simulation module 220 iterates over the run matrix cases and Monte Carlo repetitions defined in each simulation batch, running the configured simulation for each combination of case and repetition. The manner in which the batch simulation module 220 manages this execution is described in greater detail below.

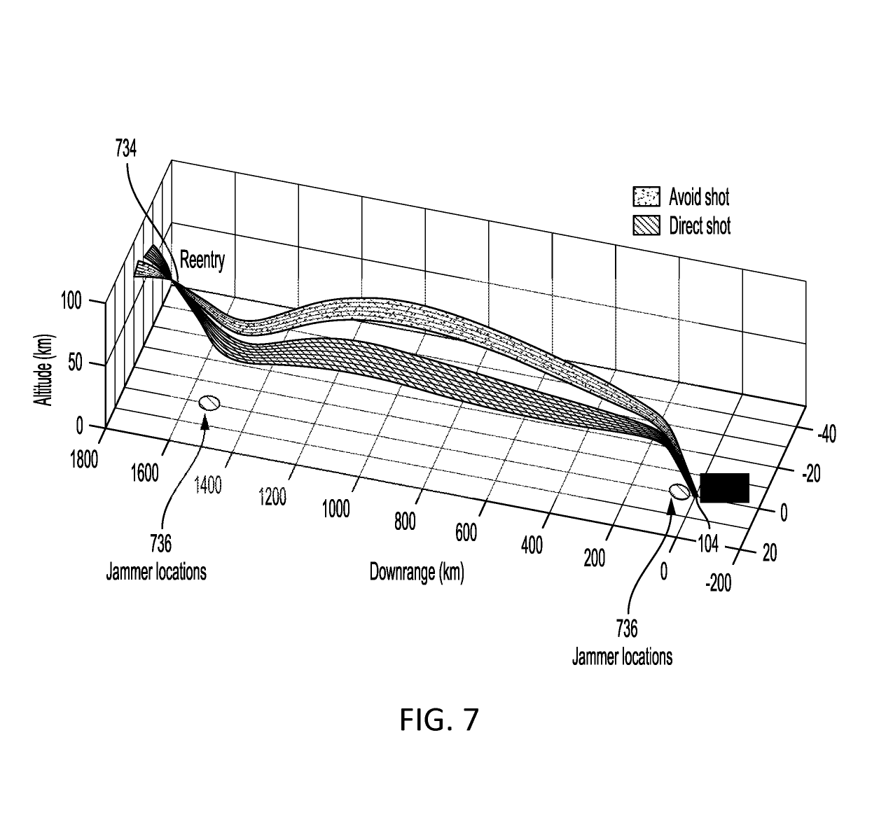

The output processor 222 receives the simulation outputs from the batch simulation module 220 and processes them to generate the simulation results 214. This includes aggregating outputs across Monte Carlo repetitions, computing measures of effectiveness (MOEs) such as circular error probable (CEP), and producing data in a form suitable for further analysis and comparison across run matrix cases. In some examples, the output processor 222 also supports custom post-processing functions that can be defined by the user and applied automatically after each batch completes. The output processor 222 can generate plots comparing outputs across run matrix cases, provide overview plots of individual runs, and produce Monte Carlo summary plots of the type shown in FIGS. 7, 8, and 9. In some examples, the output processor 222 saves simulation results to persistent storage so that prior results can be reloaded and compared against results from subsequent studies, enabling meta-analysis across multiple simulation runs without re-executing the simulations.

### 2.1 INPUT PROCESSOR

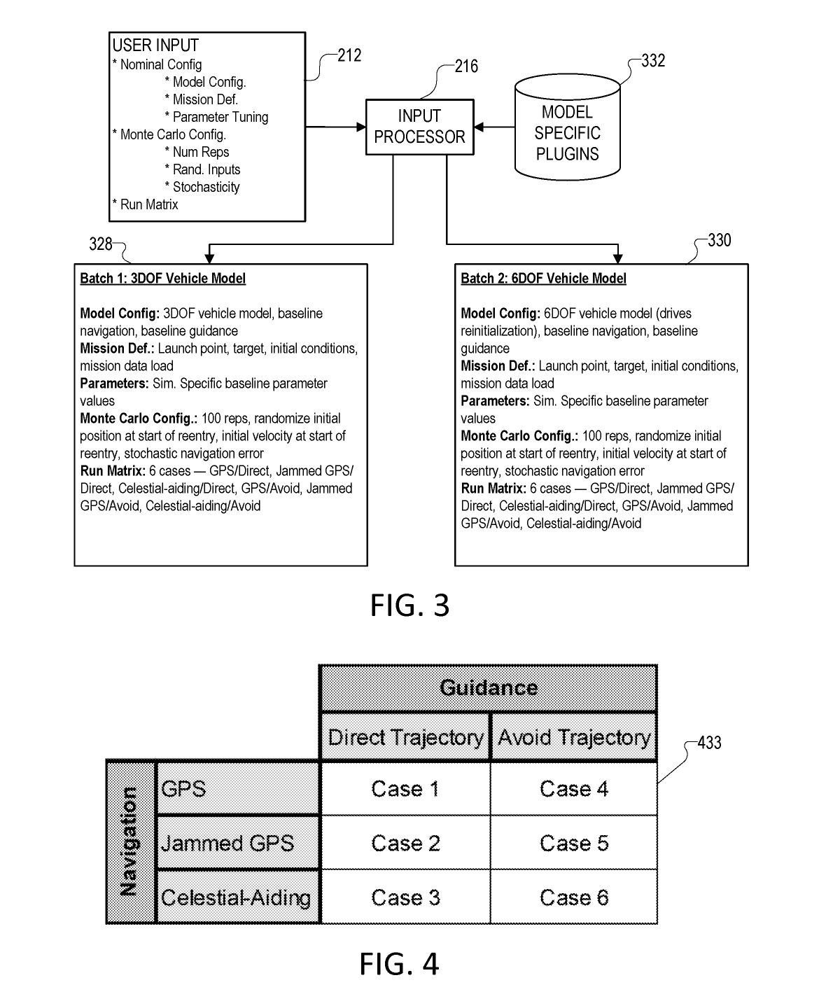

Referring to FIG. 3, an example of how the user input 212 is processed by the input processor 216 to generate simulation batches is shown in the context of the mission problem introduced in FIG. 1. In this example, a user seeks to evaluate two candidate vehicle model fidelities, a 3DOF vehicle model and a 6DOF vehicle model, each across the same set of mission scenarios. Because each vehicle model requires a distinct model configuration, the user input 212 gives rise to two simulation batches: a first batch 328, corresponding to the 3DOF vehicle model, and a second batch 330, corresponding to the 6DOF vehicle model.

The input processor 216 also receives (e.g., is configured to access) input from model-specific plugins 332. The model-specific plugins 332 provide the input processor 216 with the information needed to translate and condition the user input 212 into the format required by each vehicle model. Because different vehicle models may require parameters to be expressed in different coordinate frames, units, or data structures, the model-specific plugins 332 allow the input processor 216 to perform this translation without requiring the user to specify model-specific formatting directly. As is described in greater detail below, the input processor 216 uses the model-specific plugins 332 to convert the user input 212 into simulation batches with parameters that are formatted for compatibility with the respective vehicle model of each batch.

In the first batch 328, the model configuration specifies the 3DOF vehicle model with baseline navigation and baseline guidance. The mission definition specifies the launch point, target location, initial conditions, and mission data load. The parameter tuning values specify simulation-specific baseline parameter values for the 3DOF model. The Monte Carlo configuration specifies one hundred repetitions, with randomized initial position at the start of reentry, randomized initial velocity at the start of reentry, and stochastic navigation error. The first batch 328 also includes a run matrix 433 defining the set of cases to be evaluated, as described in greater detail below with reference to FIG. 4.

In the second batch 330, the model configuration specifies the 6DOF vehicle model, which drives reinitialization of the vehicle state, with baseline navigation and baseline guidance. The mission definition, parameter tuning values, Monte Carlo configuration, and run matrix 433 of the second batch 330 are identical to those of the first batch 328. The two batches therefore differ only in their model configuration, with the 3DOF and 6DOF vehicle models allowing the user to compare results across model fidelity levels under otherwise identical simulation conditions.

### 2.1.1 SIMDATA CLASS

In some examples, the input processor 216 operates on a simulation data object referred to herein as a simData class instance. The simData class is a data structure that contains all information needed to set up and run a simulation, including the model configuration, mission variables, random variables, parameter tuning values (ddVars), and Monte Carlo configuration. When the user provides input 212, the input processor 216 instantiates a simData class object and populates it with the user-specified values. The simData class serves as the common language between the user-facing interface and the batch simulation module 220, encapsulating all simulation inputs in a single structured object that can be passed through the execution pipeline without requiring the user to manage the underlying data formats.

The simData class includes simulator-agnostic fields that are common across all top-level models, as well as model-specific fields that are populated based on the selected model configuration. The model-specific fields are populated by the model-specific plugins 332, which supply the input processor 216 with the information needed to translate user inputs into the format required by the selected top-level model. The simData class provides a clean separation between the user-facing representation of simulation inputs and the model-specific representation required for execution.

### 2.1.2 COORDINATE FRAME TRANSFORMATION

One function of the input processor 216 is translating user-specified simulation parameters into the coordinate frames and data formats required by the selected simulation model. In a typical simulation setup, a user specifies initial conditions such as position and velocity in a human-readable coordinate frame. For example, a user may specify an initial position in terms of latitude, longitude, and altitude (LLA) and an initial velocity in terms of Mach number and flight path angle. The selected simulation model, however, may require these values in a different coordinate frame and format (e.g., position expressed in Earth-Centered Inertial (ECI) Cartesian coordinates and velocity expressed as an ECI velocity vector). The input processor 216 applies the translation logic defined by the model-specific plugin associated with the selected model to convert the user-specified values into the format required by that model before the simulation is executed.

Because the translation logic is contained in the model-specific plugin rather than hardcoded in the input processor 216, the same input processor 216 can serve multiple different simulation models, each with its own coordinate frame requirements, without modification. A user selecting a different simulation model causes the input processor 216 to apply the plugin associated with that model, which may define entirely different translation logic, without any change to how the user specifies inputs. This is one important advantage of the plugin architecture in that the user can specify inputs in the same human-readable form regardless of which model is selected, and the framework handles the model-specific translation automatically.

### 2.1.3 MONTE CARLO PERTURBATION ORDERING

When Monte Carlo perturbations are applied to simulation inputs in addition to coordinate frame transformations, the ordering in which those operations are performed becomes significant. If a coordinate frame transformation is applied before a Monte Carlo perturbation, the perturbation is applied to the already-transformed values. For example, to ECI coordinates rather than to the user-specified LLA coordinates. This produces a perturbation in the model's internal coordinate frame rather than in the physical space the user intended to randomize, and can result in simulation outputs that do not reflect the intended perturbation.

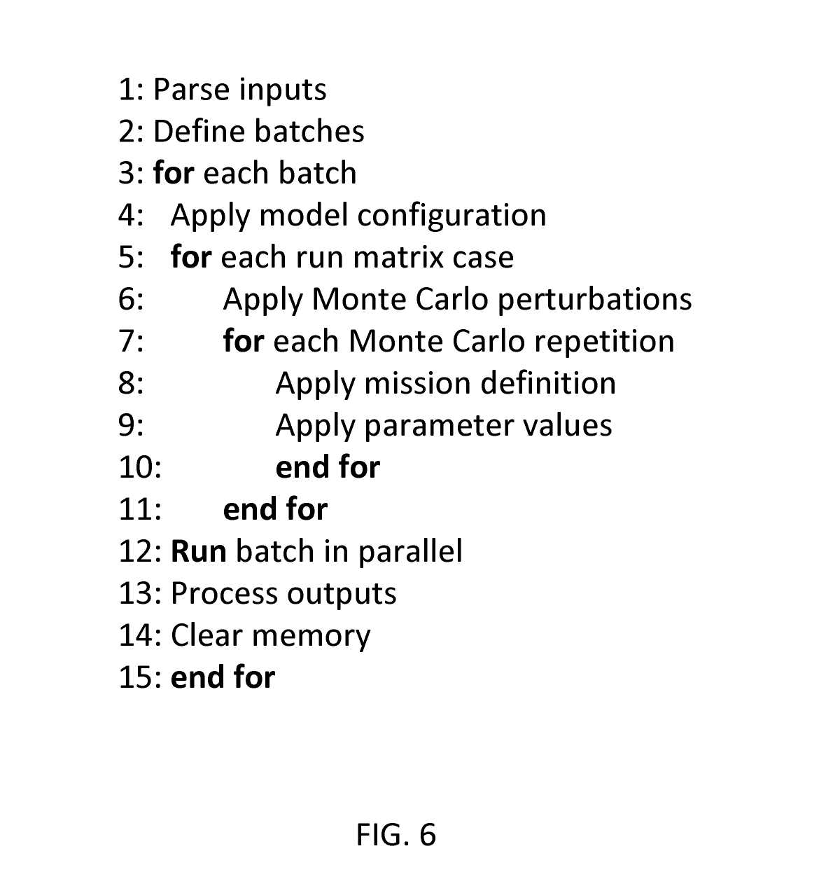

In some examples, the input processor 216 addresses this by applying Monte Carlo perturbations to the user-specified values before applying coordinate frame transformations. This ensures that the perturbations are applied in the user-specified coordinate frame, and that the transformed values passed to the simulation reflect the perturbed inputs as the user intended. This ordering is reflected in the pseudocode of FIG. 6, where Monte Carlo perturbations are applied at line 6 before the mission definition and parameter values are applied at lines 8 and 9.

Without this ordering, a user running a Monte Carlo study with perturbed initial conditions would need to manually manage the sequencing of perturbation and transformation operations across multiple scripts, creating a brittle cascade of dependencies that is prone to error and difficult to maintain as models and study configurations change. The input processor 216 enforces the correct ordering automatically, allowing the user to specify perturbations in human-readable form without needing to understand the coordinate frame dependencies of the selected model.

### 2.1.4 RUN MATRIX

Referring to FIG. 4, the run matrix 433 in this example defines six cases organized along two dimensions: navigation configuration and guidance trajectory. Along the navigation dimension, three navigation configurations are evaluated: GPS-aided navigation, GPS-jammed navigation, and celestial-aided navigation. Along the guidance dimension, two trajectory options are evaluated: a direct trajectory and an avoid trajectory, corresponding respectively to the "out-navigate" and "avoid" penetration approaches introduced in FIG. 1. The combination of three navigation configurations and two trajectory options yields six run matrix cases. Case 1 corresponds to GPS navigation with a direct trajectory. Case 2 corresponds to GPS-jammed navigation with a direct trajectory. Case 3 corresponds to celestial-aided navigation with a direct trajectory. Case 4 corresponds to GPS navigation with an avoid trajectory. Case 5 corresponds to GPS-jammed navigation with an avoid trajectory. Case 6 corresponds to celestial-aided navigation with an avoid trajectory. Because both batches 328 and 330 share the run matrix 433, each batch executes six cases, and each case is run for one hundred Monte Carlo repetitions, yielding a total of six hundred simulation runs per batch.

### 2.2 BATCH SIMULATION MODULE

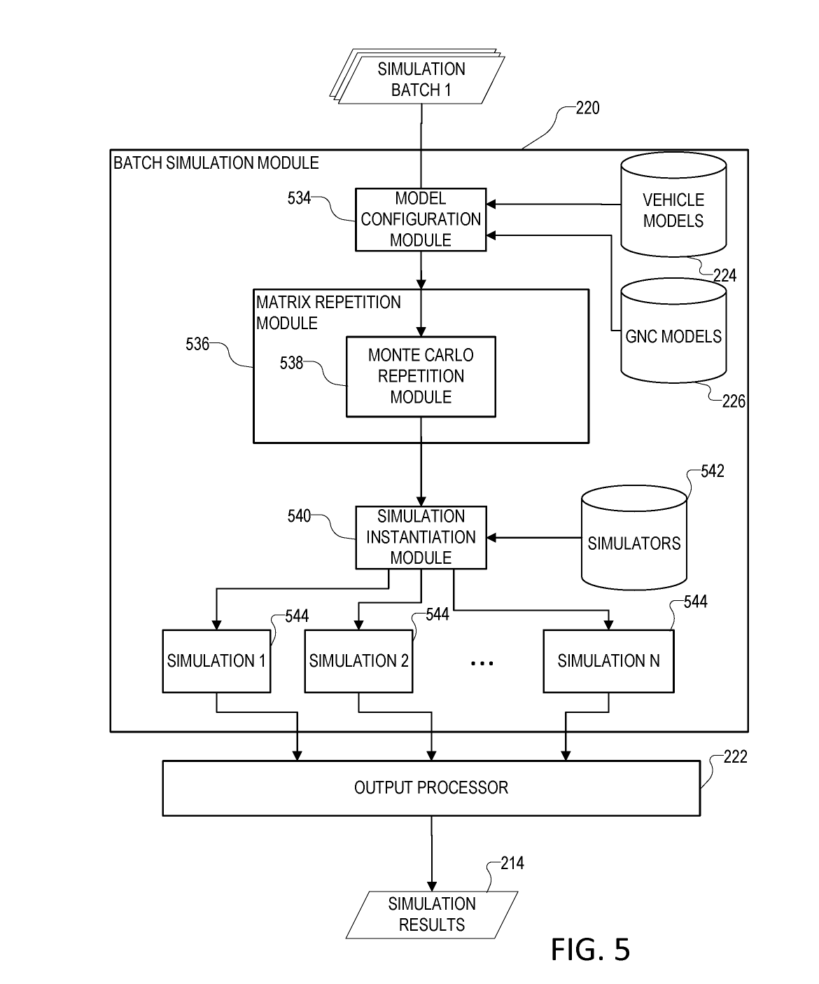

Referring to FIG. 5, the batch simulation module 220 processes each simulation batch by configuring the simulation models called for by that batch, iterating over the run matrix cases and Monte Carlo repetitions defined in the batch, and then executing the resulting set of simulation runs in parallel. The outputs of those runs are passed to the output processor 222 to generate the simulation results 214. The batch simulation module 220 includes a model configuration module 534, a matrix repetition module 536, a Monte Carlo repetition module 538, and a simulation instantiation module 540.

The model configuration module 534 receives a simulation batch and configures the simulation environment called for by the batch's model configuration. In the example of FIGS. 3 and 4, the model configuration module 534 draws on the vehicle models 224 and GNC models 226 to assemble the simulation environment specified by the batch. For the first batch 328, the model configuration module 534 configures a 3DOF vehicle model with baseline navigation and baseline guidance. For the second batch 330, the model configuration module 534 configures a 6DOF vehicle model with baseline navigation and baseline guidance. Because the model configuration is applied once per batch, before any run matrix iteration begins, a change in model configuration defines the boundary between batches.

The matrix repetition module 536 iterates over the run matrix cases defined in the batch. For each case in the run matrix 433, the matrix repetition module 536 applies the navigation configuration and guidance trajectory specified by that case before passing control to the Monte Carlo repetition module 538. In the example of FIG. 4, the matrix repetition module 536 iterates over all six cases for each batch, applying the appropriate navigation configuration and trajectory type for each.

Nested within the matrix repetition module 536, the Monte Carlo repetition module 538 iterates over the Monte Carlo repetitions specified in the batch's Monte Carlo configuration. For each repetition, the Monte Carlo repetition module 538 applies the specified random perturbations to the mission definition and parameter values before the simulation is run. In the example of FIGS. 3 and 4, the Monte Carlo repetition module 538 applies 100 repetitions per case, randomizing initial position at the start of reentry, initial velocity at the start of reentry, and stochastic navigation error. In some examples, the Monte Carlo perturbations are applied before the mission definition and parameter values are applied, so that the perturbed values serve as the inputs to the simulation rather than above as modifications to already-applied mission parameters. As is described in greater detail below, this ordering is a deliberate aspect of the framework's input processing architecture.

The simulation instantiation module 540 receives the fully configured set of simulation runs produced by the matrix repetition module 536 and Monte Carlo repetition module 538 and instantiates the simulations for parallel execution. The simulation instantiation module 540 draws on a library of simulators 542 to instantiate each simulation run. In the example of FIGS. 3 and 4, each batch produces 600 simulation runs, representing six run matrix cases each executed for one hundred Monte Carlo repetitions. The simulation instantiation module 540 instantiates these runs as simulations 544, which execute in parallel. The outputs of simulations 544 are passed to the output processor 222, which aggregates the results and computes the simulation results 214 as described above.

FIG. 6 is pseudocode for the execution loop of the batch simulation module 220. The pseudocode reflects the nested loop structure described above with reference to FIG. 5. At line 1, the framework parses the user input 212. At line 2, the framework defines the simulation batches, corresponding to the first batch 328 and second batch 330 of the example described above. Lines 3 through 15 define the outer loop that iterates over each batch. At line 4, the model configuration is applied once per batch, outside of the run matrix loop, confirming that a change in model configuration defines the boundary between batches rather than between run matrix cases. Lines 5 through 11 define the inner loop that iterates over each run matrix case. At line 6, Monte Carlo perturbations are applied to the mission definition and parameter values before the Monte Carlo repetition loop begins at line 7. This ordering ensures that the perturbations are applied to the nominal values rather than to values that have already been modified by a prior repetition. Lines 8 and 9 apply the mission definition and parameter values for each Monte Carlo repetition. At line 12, the fully configured set of simulation runs for the batch is executed in parallel. At line 13, outputs are processed. At line 14, memory is cleared before the next batch begins.

### 2.3 SIMULATION RESULTS

Referring to FIG. 7, example simulation results 214 generated by the modeling and simulation framework 210 for the mission problem introduced in FIG. 1 are shown. Specifically, FIG. 7 shows a three-dimensional trajectory plot of the Monte Carlo trajectory ensemble for two of the six run matrix cases defined in FIG. 4: the direct trajectory cases and the avoid trajectory cases. The trajectories are plotted in terms of downrange distance, crossrange distance, and altitude, and originate from a common reentry point 734 and terminate at the target 104. Jammer locations 736 are also shown in the mission geometry for reference.

The spread of trajectories within each case represents the Monte Carlo variation across the 100 repetitions, reflecting the effect of the randomized initial position, randomized initial velocity, and stochastic navigation error applied by the Monte Carlo repetition module 538. The direct trajectory cases follow a more direct path from the reentry point 734 to the target 104, passing in closer proximity to the jammer locations 736. The avoid trajectory cases arc to a higher cross-range and follow a longer downrange path that routes around the jammer locations 736 before descending toward the target 104. The relative spread of the two trajectory ensembles provides a visual indication of how navigation uncertainty propagates differently across the two guidance approaches under Monte Carlo variation.

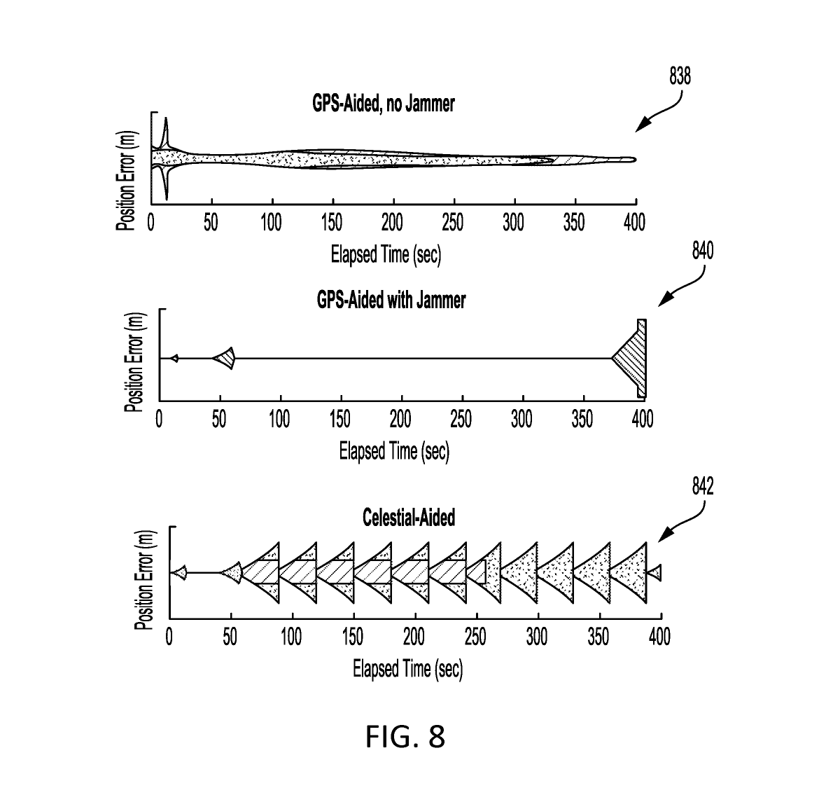

Referring to FIG. 8, additional simulation results 214 generated by the modeling and simulation framework 210 are shown in the form of navigation position error over elapsed flight time. FIG. 8 includes three plots, each corresponding to a different navigation configuration from the run matrix 433. Each plot shows position error in meters on the vertical axis and elapsed time in seconds on the horizontal axis, with the spread of traces across the Monte Carlo repetitions visible in each plot.

The first plot 838 corresponds to GPS-aided navigation in an unjammed environment, representing Cases 1 and 4 of the run matrix 433. In this configuration, position error converges rapidly after reentry and remains low throughout the flight, yielding a circular error probable (CEP) of less than one meter. The second plot 840 corresponds to GPS-aided navigation in the presence of a jammer, representing Cases 2 and 5 of the run matrix 433. In this configuration, GPS signals are denied beginning at approximately 60 seconds and 375 seconds into the flight. After about 375 seconds position error grows substantially. The third plot 842 corresponds to celestial-aided navigation, representing Cases 3 and 6 of the run matrix 433. In this configuration, position error exhibits a periodic pattern reflecting the discrete update intervals of the celestial navigation sensor.

The three plots collectively illustrate how the modeling and simulation framework 210 enables direct comparison of navigation architecture performance across run matrix cases under identical Monte Carlo conditions, providing the quantitative basis for navigation design trade decisions of the type introduced in FIG. 1.

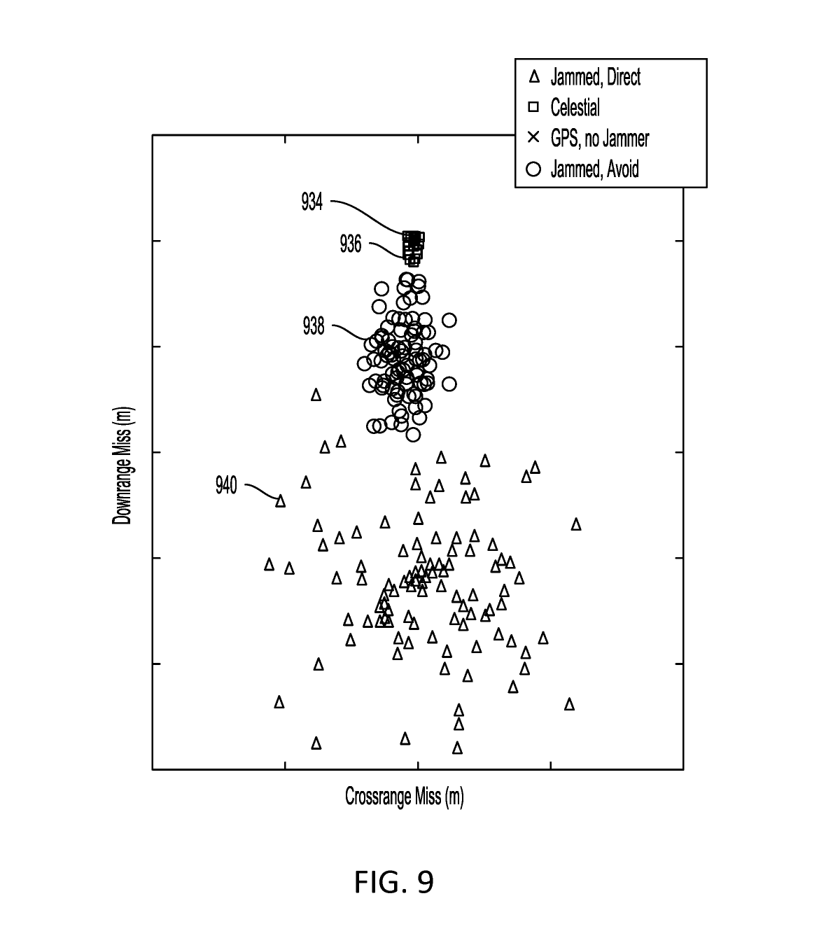

Referring to FIG. 9, additional simulation results 214 generated by the modeling and simulation framework 210 are shown in the form of a miss distance scatter plot. The plot shows downrange miss distance in meters on the vertical axis and crossrange miss distance in meters on the horizontal axis, with each data point representing the terminal impact location of a single Monte Carlo repetition relative to the target 104. Four run matrix cases are represented in the plot: GPS-aided navigation with no jammer, celestial-aided navigation, GPS-jammed navigation with a direct trajectory, and GPS-jammed navigation with an avoid trajectory.

The GPS-aided navigation cases 934 exhibit tight clustering near the target 104, with impact points concentrated within a few meters in both the downrange and crossrange directions, consistent with the CEP shown in FIG. 8. The celestial-aided navigation cases 936 also cluster tightly near the target 104, with a slightly larger but still compact dispersion, consistent with the CEP shown in FIG. 8. The GPS-jammed navigation with avoid trajectory cases 938 exhibit a moderate dispersion concentrated primarily in the downrange direction, indicating that the avoid trajectory partially mitigates the effect of GPS jamming by reducing exposure time to the jammer. The GPS-jammed navigation with direct trajectory cases 940 exhibit the largest dispersion, with impact points scattered broadly in both the downrange and crossrange directions, consistent with the CEP shown in FIG. 8.

Taken together, FIGS. 7, 8, and 9 illustrate the type of simulation results 214 that the modeling and simulation framework 210 is capable of generating from a single study setup, enabling direct quantitative comparison of candidate GNC architectures across the run matrix cases defined in FIG. 4.

### 3. ALTERNATIVES

### 3.1 PLUG-IN INTERFACE

In some examples, the model-specific plugins 332 conform to a defined plug-in interface that specifies the inputs and outputs required of each plugin. A developer integrating a new top-level model into the modeling and simulation framework 210 does so by writing a plugin that implements the plug-in interface for that model. The plugin encapsulates the model-specific translation logic, including the coordinate frame requirements of the model, the data structures it expects, and any other model-specific formatting requirements. Once the plugin is written, the input processor 216 can apply it automatically whenever the corresponding model is selected, without requiring changes to the simulator-agnostic portions of the input processor 216 or the simData class. The plug-in architecture enables the modeling and simulation framework 210 to be extended to support new models without modifying the core framework.

In some examples, the plugin library grows over time as developers contribute plugins for new models. Because coordinate frame transformations and other translation operations are encapsulated in the plugins rather than hardcoded in the input processor 216, a transformation developed for one model can be reused by other models that share the same coordinate frame requirements, reducing redundant development effort.

### 3.2 USER INTERFACE AND CONFIGURATION FILES

In some examples, the user provides the user input 212 through a graphical user interface (GUI) that presents the model configuration, mission definition, parameter tuning, Monte Carlo configuration, and run matrix inputs in a human-readable form. The GUI produces a configuration file, such as a JSON or MAT file, that encodes the user-specified values. The input processor 216 reads the configuration file and instantiates the simData class object accordingly. This architecture allows the modeling and simulation framework 210 to be operated interactively through the GUI or headlessly from a script, with the configuration file serving as the interface between the two modes of operation. In some examples, the configuration file can be saved and reloaded, allowing a user to reproduce a prior simulation study exactly or to share a study configuration with other users.

### 3.3 PARALLEL EXECUTION AND MEMORY MANAGEMENT

In some examples, the simulation instantiation module 540 uses a parallel computing framework to execute the simulation runs in a batch concurrently across multiple processor cores or compute nodes. The number of parallel workers and the allocation of simulations to workers can be configured as part of the user input 212. In some examples, the simulations are compiled ahead of execution using an accelerator mode, in which the simulation model is pre-compiled prior to runtime to reduce per-run execution overhead. After all runs in a batch are complete and their outputs are processed by the output processor 222, the modeling and simulation framework 210 clears the simulation data from memory before proceeding to the next batch, as shown at line 14 of the pseudocode in FIG. 6. This memory management step allows large multi-batch studies to be executed without accumulating memory consumption across batches.

### 3.4 EXTENSIBILITY TO ADDITIONAL VEHICLE AND GNC MODELS

In some examples, the vehicle models 224 and GNC models 226 are organized as modular subsystem references that can be independently developed, tested, and substituted within a top-level model. The vehicle models 224 can include, for example, 3DOF point-mass models, pseudo-6DOF models, and full 6DOF models representing rigid body dynamics. The GNC models 226 can include guidance laws such as proportional navigation, quasi-equilibrium glide guidance, Euler angle guidance, and aerodynamic angle guidance, as well as navigation architectures including passthrough navigation, stochastic navigation, and loosely coupled INS/GNSS navigation.

In stochastic navigation, the simulation is first run without navigation processing, and the resulting trajectory is provided to an external navigation analysis tool that returns state uncertainties based on a selected navigation architecture. These uncertainties are fed back into the framework and used to stochastically generate the state estimate for each Monte Carlo repetition.

Because each subsystem is implemented as a modular reference, a developer can substitute one subsystem for another, for example swapping one navigation model for another, without modifying the rest of the top-level model. The model configuration specified in the user input 212 selects the combination of subsystems to be assembled by the model configuration module 534 for a given batch.

### 3.5 SIMULATION STOP CONDITIONS

In some examples, the user input 212 includes one or more stop conditions that define the criteria under which each simulation run terminates. Stop conditions can include threshold values for quantities such as range-to-target, closing speed, altitude, and airspeed, with each condition defined by an upper bound, a lower bound, or both. A simulation run terminates when any active stop condition is triggered or satisfied (e.g., when the monitored quantity falls below its lower bound or rises above its upper bound). In some examples, a simulation run may terminate before a user-specified maximum duration if a stop condition is triggered first. Stop conditions allow the framework to automatically terminate simulation runs that have reached a meaningful physical endpoint, such as target intercept or ground impact, without requiring the user to specify a fixed simulation duration that accommodates all possible run outcomes.

### 3.6 PARAMETER SWEEPS AND SENSITIVITY ANALYSIS

In some examples, the run matrix 433 is populated using sweep variables rather than manually specified case definitions. A sweep variable defines a range or set of discrete values for a particular input, and the run matrix is automatically expanded to include one case for each combination of sweep variable values. For example, a sweep across three flight path angles, two azimuth angles, and four initial velocity values produces a run matrix of twenty-four cases, one for each combination of the three sweep dimensions. This capability supports sensitivity analysis, kinematic envelope exploration, parameter tuning, and design-of-experiments studies, in addition to the navigation architecture trade studies illustrated in FIGS. 4-9. In some examples, sweep variable values are generated by an external tool and provided to the input processor 216 as a pre-defined run matrix, allowing the modeling and simulation framework 210 to serve as the execution backend for studies designed in external analysis environments.

### 3.7 ADDITIONAL APPLICATIONS

Although the examples described herein are presented in the context of simulating hypersonic missile mission cases and evaluating GNC architecture options for long-range strike missions, the modeling and simulation framework 210 is not limited to that application. The framework is applicable to any domain in which a user seeks to evaluate multiple candidate system configurations across a common set of scenarios using physics-based simulation with Monte Carlo analysis. For example, the modeling and simulation framework 210 may be used to evaluate navigation and guidance architectures for launch vehicles, satellites, or spacecraft, where candidate configurations may vary in propulsion systems, attitude control methods, or orbital insertion strategies. The framework may also be used in the design of autonomous aerial vehicles, where candidate GNC architectures are evaluated across varying wind conditions, sensor failure scenarios, or obstacle environments. In maritime applications, the framework may be used to evaluate candidate navigation systems for surface or undersea vehicles operating in contested environments. In automotive applications, the framework may be used to evaluate autonomous driving algorithms across varying road conditions, sensor configurations, and traffic scenarios. More generally, the modeling and simulation framework 210 is applicable to any simulation domain in which a top-level model can be configured through a set of model-specific parameters, and in which a user wishes to efficiently execute and compare simulation results across multiple model configurations, mission scenarios, and stochastic perturbations without manually managing the translation of inputs between human-readable form and model-compatible format.

The following section describes additional details and embodiments of the modeling and simulation framework 210 that are within the scope of the disclosure.

### 4. ADDITIONAL DETAILS AND EMBODIMENTS

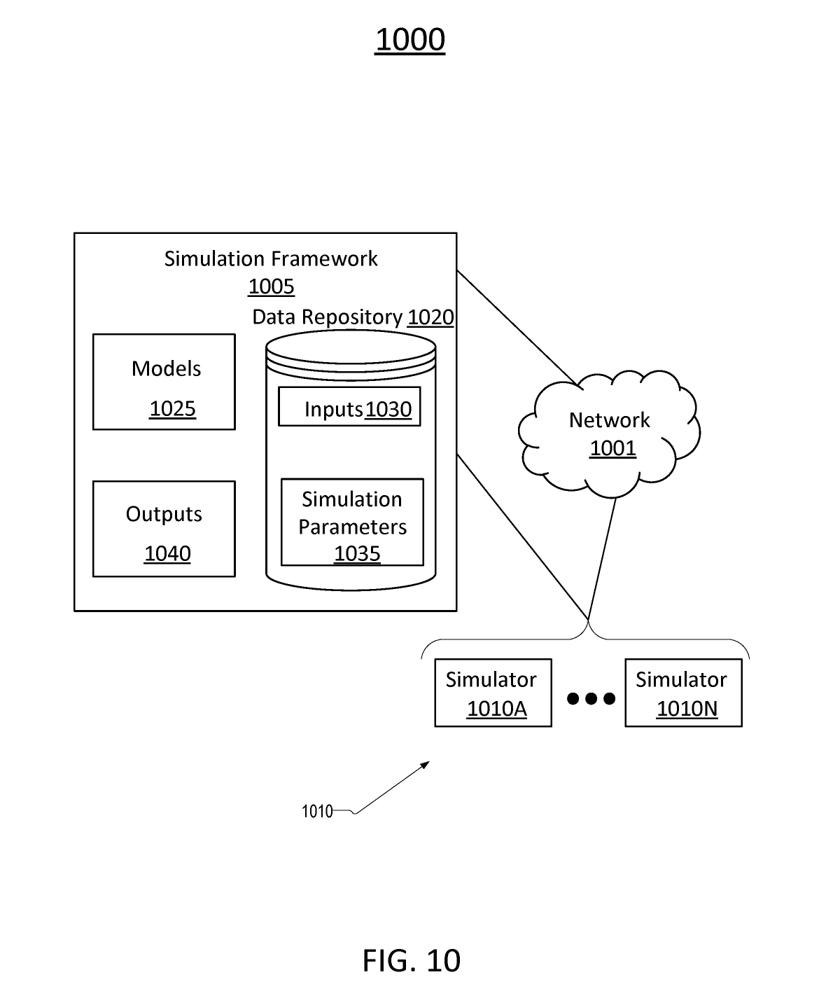

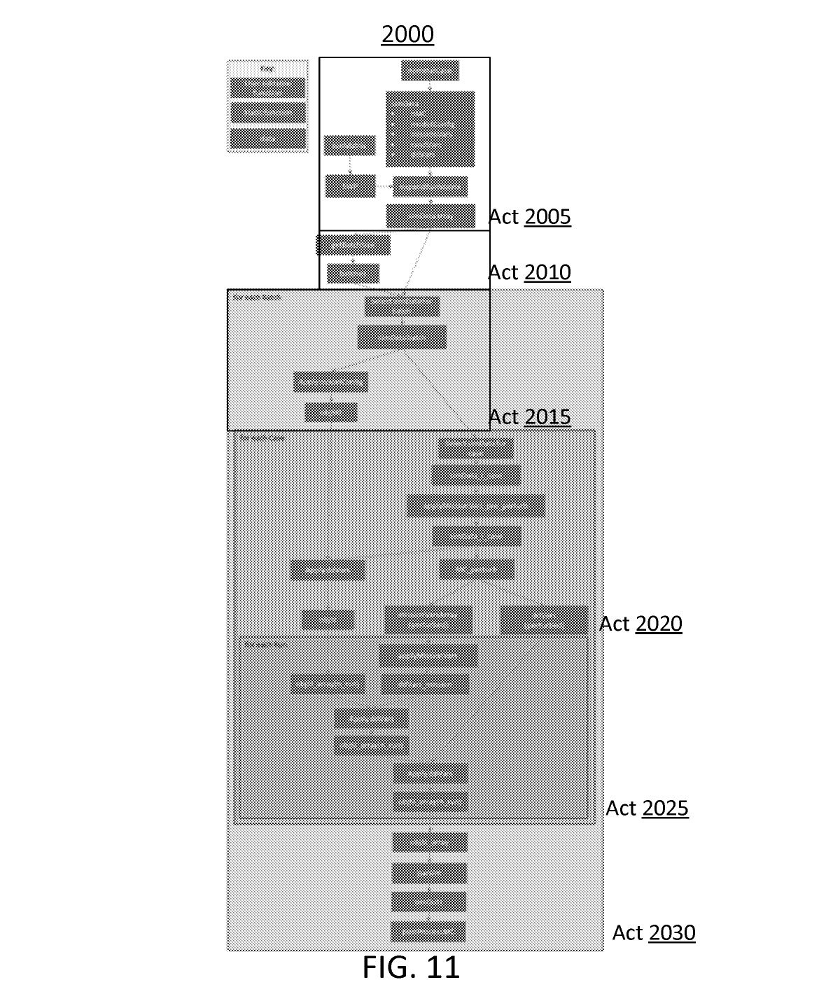

FIG. 10 depicts a diagram of a system 1000 for flight simulations. The system can include a simulation framework 1005, a network 1001, and one or more simulators (e.g., simulator 1010A to simulator 1010N, also referred to herein as the “simulator(s) 1010”). The simulation framework 1005 can include models 1025, a data repository 1020 including inputs 1030 and simulation parameters 1035, and outputs 1040. In brief overview of the system 1000, the simulation framework 1005 can provide various subsets of the inputs 1030 to the models 1025 according to the outputs 1040. The models 1025 can, according to a sequence defined by the outputs 1040 and the models 1025, generate a first set of simulation parameters 1035. The simulation framework 1005 can generate, based on the first set of simulation parameters 1035 and a particular simulator 1010A of the simulators 1010A-N, a second set of simulation parameters 1035 compatible with the particular simulator 1010A. Embodiments may comprise additional or alternative components or omit certain components from those of FIG. 10, and still fall within the scope of this disclosure.

The network 1001 can include various hardware and software components of one or more public or private networks, which can interconnect the various components of the system 1000. Non-limiting examples of such networks can include Local Area Network (LAN), Wireless Local Area Network (WLAN), Metropolitan Area Network (MAN), Wide Area Network (WAN), and the Internet. The communication over the network can be performed in accordance with various communication protocols, such as Transmission Control Protocol and Internet Protocol (TCP/IP), User Datagram Protocol (UDP), and IEEE communication protocols, among others. In some cases, the network 1001 can include a hardwired connection, such as fiber optic, copper, ethernet or other electrically or communicatively conductive wiring or other communications cables to transmit communication, power, or other signals among the various components of the system 1000, such as one or more of the simulators 1010.

The simulators 1010 can be or include various simulation software, algorithms, or programs operable via hardware, software, or a combination thereof to simulate various aspects of physics, dynamics, trajectory, navigation, thermodynamics, electricity, or artificial intelligence, among others. For example, a simulator of the simulators 1010 can include a text-based interface for performing matrix calculations, a program for modeling various forces and frictions on a moving body, or other such software which may be useful in modeling or simulating vehicle movements in certain environments. Notably, each simulator 1010 cannot account for the intricacies of various desired simulated outputs, such as the outputs 1040, due to intrinsic operation of the simulator 1010 such as limitations on inputs or changes to those inputs and lack of interoperability between the various simulators 1010. The simulators 1010 can accept as input a set of simulation parameters 1035, generated by the simulation framework 1005 or a component thereof.

The outputs 1040 can be or include any of a variety of desired simulations, comparisons, output graphs, or other such data. The outputs 1040 can include, for example, sensitivity analyses, parameter tuning, kinematic envelope exploration, accuracy analysis, guidance robustness, controllability analysis, analysis of alternatives, trajectory comparisons, etc.

In some cases, the outputs can be desired outputs and included in the inputs 1030. The inputs 1030 are definitions, configurations, values, or algorithms set for undergoing a simulation to provide a desired output, such as the output 1040. The inputs 1030 can be user selected, such as input by a user of the simulation framework via a graphical user interface (GUI) operating on a user device. The inputs 1030 can be received from one or more of the simulators 1010A. For example, a first simulator 1010A can provide an algorithm, matrix, object definition, or other such input to the simulation framework 1005.

The inputs 1030 can include user defined inputs, such as nominal configurations, model configurations, mission definitions, parameter tuning, Monte Carlo configurations, number of repetitions, randomized inputs, stochasticity, run matrix, among others as described herein.

The inputs 1030 can include model configurations, such as inputs to define operation of the models 1025. Such inputs can include a listing of vehicles or properties thereof, such as formulas defining shape, inertia, computer-aided drawings (CAD), material properties, location, acceleration, velocity, position, etc. Model configurations can include a vehicle stage list, corresponding to changes to aspects of the vehicle during the simulation such as weight loss due to fuel over time, change in dynamics of the vehicle, etc. Model configurations can include one or more algorithms, methods, or calculations included in one or more of the simulators 1010, and inputs related therein. Model configurations can include a start time for the simulation, such as a start time in the future, past, or the current time. Model configurations can include a duration of the simulation, or conditions to end the simulation. In some cases, each model simulation is not guaranteed to reach this duration as other stop conditions within the model can end the simulation before the maximum duration is triggered. Model configurations can include a time step size that the model simulation takes at each integration step. Model configurations can include degrees of freedom, such as 3 degrees of freedom, 4 degrees of freedom, 6 degrees of freedom, etc.

Model configurations can include selection of desired models, such as a sensor model, navigation model, among others. Examples of navigation models can include perfect or stochastic, among others. The inputs 1030 can include which atmosphere model to use within the navigation model, such as COESA, ISA, Laspe Rate, or Non-Standard Day, among others. The inputs 1030 can include a selection of gravity models such as Zonal Harmonic, WGS84, or Centrifugal Effect, among others.

The inputs 1030 can include model stop conditions. The model stop conditions can determine which stop conditions are active as well as define the upper and lower bounds for each stop condition. The bounds are defined as such; if the value falls below the lower bound, the model simulation will stop, or if the value rises above the upper bound the model simulation will stop. For example, a simulation can stop based on a variety of conditions. Examples include target distances between the vehicle and an object, threshold speeds, simulation run time, etc.

The inputs 1030 can include defining a Range-To-Target, i.e. a distance between the vehicle and a target (such as a landing location, other vehicle, etc.). The inputs 1030 can include a Closing Speed, i.e. a speed at which the vehicle is approaching the target. The inputs 1030 can include an altitude, i.e., height of the vehicle above the ground, an airspeed, i.e., an air relative to the speed of the vehicle.

The inputs 1030 can include simulation and output configurations. The simulation and output configurations define some aspects of how the overall simulation will run. For example, the simulation and output configurations can include an accelerator mode, which determines usage of a functionality of at least one of the simulators 1010. For example, accelerator mode can be a tag to indicate to a model to pre-compile prior to run time. Other inputs 1030 can determine parallelism of various model operations. The inputs 1030 can include a batch size, such as a size of operations, definitions, or other parameters to include in a batch running of the simulation. The inputs 1030 can determine a display of the outputs 1040, such as plots, graphics, or descriptions of the simulated outputs 1040.

The inputs 1030 can defines the drive letter which the simulation should use, a number of simulations, a number of workers.

The inputs 1030 can include mission variables. The mission variables enable customization of initial conditions for both the vehicle and the target. The mission variables can include a position. For example, the position can include an initial position of the vehicle and/or target. Position values can be defined in (Latitude, Longitude, Altitude), or in ECI (X, Y, Z), among other coordinates. Position values can be defined in terms of distances, such as a distance between the target and the vehicle.

The mission variables can include an initial velocity of the vehicle/target. For example, an initial velocity can include a Mach value, a magnitude, an angle and azimuth, or in ECI (vX, vY, vZ). The mission variables can include an azimuth. For example, the inputs 1030 can include a definition of an initial azimuth angle of the vehicle/target. The mission variables can defines an initial flight path angle of the vehicle/target, such as in degrees or radians.

The inputs 1030 can include random variables. Any of the inputs 1030 can include random variables, such as the mission variables, model configurations, simulation and output configurations, among others. For example, the inputs can include values to randomize across each Monte Carlo run of a simulation. Random variables can include a distribution type, sigma value, and mean, among other values. In some cases, adding random variables does not add more runs or simulations.

The inputs 1030 can include sweep variables. Any of the inputs 1030 can include sweep variables, such as the mission variables, model configurations, simulation and output configurations, among others. The sweep variables can include values to sweep across between Monte Carlo runs. In some cases, each sweep variable added will add additional simulations. A simulation with multiple sweep variables will run N simulations where N is the product of the amount of each variable sweep used (i.e., a full factorial experiment or full factorial design). For example, a sweep using 3 values for flight path angle, 2 azimuth angles, and 4 velocity values would run 24(3*2*4=24) simulations, one for each combination of sweep variables.

The models 1025 can receive one or more of the inputs 1030. In some cases, subsets of the inputs 1030 are provided to subsets of the models 1025. For example, a subset of the inputs 1030 can be provided to a first model and a second subset of inputs 1030 can be provided to a second model. The inputs can be provided to the models 1025 sequentially, en masse, parallelly, responsive to a determination by another model, at a specified time, among others.

In some cases, the inputs 1030 can include or designate one or more perturbations that are inputs for the Monte Carlo analysis. The one or more perturbations can be changes, alterations, or events that occur during the course of a simulation which may affect an outcome of a simulation. In some cases, an output 1040 corresponds with one or more perturbations. For example, a first output can include manifestation of a flight path for a vehicle. In this example, the first output can be realized through one simulation if no inputs vary. For example, a second output can include multiple flight paths for the vehicle if one or more perturbations are defined in the inputs 1030. The perturbations can cause the simulation to vary along one or more of its inputs as a function of time, distance, among others. For example, the perturbation can include an interaction with another vehicle within the vehicle’s flight path, differing initial times of flight start, failure scenarios of one or more components of the vehicle, among others. In this manner, the simulation framework can provide multiple simulations with varied inputs to examine various desired outputs. The simulation framework can provide for exploring variations in a trajectory or flight path of a vehicle based on interfering objects, differing environmental conditions, or different vehicles, among other various perturbations. The simulation framework can enable the exploration of performance of various GNC algorithms by providing perturbations which cause differing flight path behavior according to a selected GNC algorithm.

The system can initialize the model 1025 (or one or more models) based on the inputs 1030. The inputs 1030 may need to be able to be changed to accommodate a variety of use cases, such as caused by perturbations or various desired outputs 1040. The simulation framework 1005 can include the data repository 1020. The data repository 1020 can be any combination of hardware or software configured to store, read, write, or otherwise manage data such as the inputs 1030 or the simulation parameters. The data repository 1020 can store data in a variety of forms, such as data structures, relational databases, bus objects, or data dictionaries, among others.

In some cases, the simulation framework uses data dictionaries (DD) to store and manage simulation data. A DD allows for the data to be generated and changed external to the simulation and they can referenced by other DDs. In some cases, a particular model of the models 1025 corresponds to a parent DD, which thereafter can reference other, smaller DD. For example, the main DD may contain data pertaining to GNC parameters and bus objects, and it may reference another, smaller DD that contains the information necessary for the vehicle model. In this manner, DD’s can be generated according to a pre-determined structure for each vehicle, making it easier to change between vehicles by changing out the DD, as opposed to re-writing the data for a simulation of each different vehicle.

A bus object is structure data type corresponding to or readable by a particular simulator 1010. However, instead of having to be filled with actual data, a bus simply pre-defines the architecture that the data fits into. Therefore, when using data that would be stored like a structure, bus objects allow that data to be passed between subsystems while also reducing model clutter. Bus objects are especially useful when a certain data architecture may be used in multiple places in the simulation. For example, the 'state' bus created in the dynamics has the same structure as that of the estimates coming out of the navigator, and having the bus object simply defines an architecture for that the different data sources can fit into.

The models 1025 can be or include various subsystems of the simulation framework 1005. In some cases, a subsystem can correspond to a particular simulator 1010. Each subsystem can be edited individually, instead of needing to edit from the entire simulation, and can be interchanged with relative ease. In this manner, subsystems enable modularity of the system. For example, the subsystem can include different atmosphere models or navigation architectures, as can be defined in the inputs 1030. By aligning models 1025 with subsystems which reference the simulator 1010, changing of inputs 1030 is streamlined.

A masked subsystem is a type of subsystem reference that has specific data associated with it. This is how the DD for the vehicle model, described above, could be applied to the simulation. A masked subsystem may reference the variables or DD containing the vehicle information, and as long as the variable or DD follow a given format, then there would be no other changes to make in the model when making these adjustments. In general, a masked subsystem can be used to more easily transition between datasets used in that portion of the simulation.

The models 1025 can generate a first set of parameters of the simulation parameters 1035. The models 1025 can generate the first set of simulation parameters for any or each of the simulators based on the inputs 1030 and the outputs 1040. For example, the models 1025 can generate one or more matrices according to the inputs 1030 and the outputs 1040. The simulation parameters 1035 can include various data structures that can describe a full state of the system or intermediate signals such as the state of the vehicle, guidance commands (both Euler angle and aerodynamic angle depending on guidance selection, the resulting angle of attack and desired throttle value calculated from the controller contain in the autopilot, among others. The models 1025 can perform various calculations to generate the first set of parameters, such as according to algorithms selected as inputs and described herein. In some cases, the models 1025 can accept one or more values from the simulation parameters 1035 to generate other simulation parameters 1035.

The models 1025 can include a guidance subsystem or class. The guidance class is set up to take a subset of the inputs 1030, such as inputted actionable parameters and their respective bounds, and add the minimum and maximum bounds associated with each parameter to minimum and maximum arrays defined by the class. These minimum and maximum arrays are housed within the defined guidance class/structure. These arrays are then used within the model and act as a switch to inform the model when to change the guidance mode/algorithm. For a given set of inputs 1030, a "truth array" is created which contains the actionable parameter values of the vehicle at that given time within the simulation. This truth array is compared to the min and max arrays to determine whether to switch guidance mode or not.

The models 1025 can include a dynamics model. The Dynamics subsystem captures the summation of all the forces and moments experienced by the vehicle and updates and propagates all states forward in time. For example, the dynamics model can take inputs 1030 such as time, stage, initial state, and guidance mode information, or an angle of attack commanded from the autopilot, among others.

The models 1025 can include a common stage dynamic subsystem. This subsystem can include operations to calculate and sum the forces experienced by the vehicle by a number of different sources, as well as integrate the vehicle's state based on the calculated acceleration. In some cases, there are just as many common stage dynamic models as there are stages of the vehicle, and each includes unique information of each stage.

In some cases, the models 1025 can include a propulsion subsystem. The propulsion subsystem, when applicable, takes in the current state as well as the angle of attack and throttle commands from the autopilot to calculate the force vector from any thrust occurring. Also calculated in this subsystem is the mass flow rate of the propellant.

In some cases, the models 1025 can include an aero subsystem. The aero subsystem considers the flight conditions and the configuration of the control systems of the vehicle to calculate the force vector created by the aerodynamics by looking up the CL and CD values for that vehicle.

In some cases, the models 1025 can include a gravity subsystem. The gravity subsystem can take the gravity vector in the NED frame, which is stored along with the state and calculated from the current position, and converts it to a force vector in the ECI frame according to the selected gravity model.

In some cases, the models 1025 can include an integrator subsystem. An acceleration vector can be provided to the Integrator subsystem where it is integrated to retrieve velocity and position. The mass flow rate of the fuel is also integrated here in order to track how much propellant has been used. When the model is initialized and begins, it starts in this block; the integrators read in the initial conditions and then execute the rest of the simulation sequentially from here.

In some cases, the models 1025 can include a target model subsystem. The target model subsystem can include target dynamics, as well as the state comparison logic. In some cases, the models 1025 can include a state comparison model. The State Comparison model calculates target related information such as the range 2 target, time to go, and closing speed.

The models 1025 can include a navigation subsystem. The navigation subsystem houses both the navigation sensors and the navigation filter or method selected. Sensor models will be used to generate measurements, and these measurements will be fused with the propagated state from the dynamics to create a state estimate. These estimates will then be the information that the autopilot uses to make guidance and control decisions. Navigation methods can include Passthrough Navigation, wherein the true state is passed through as the estimate, with no navigation being performed. Navigation methods can include Stochastic Navigation, wherein the simulation is first run without any navigation (i.e. Passthrough navigation), and then this trajectory is fed into a simulator of the simulators 1010.The simulator provides state uncertainties based on a certain navigation architecture, and these uncertainties are fed back into the models 1025 where they are used to stochastically create the state estimate. The navigation methods can include Loosely-Coupled INS/GNSS, wherein an inertial measurement unit (IMU) and GNSS receiver are modeled and the measurements merged to create the estimate.

The models 1025 can include a guidance subsystem. The guidance subsystem can hold the selectable guidance laws available as inputs 1030. The guidance structure is used to standardize the inputs into the guidance manager as well as allow the user to define their own guidance switches/triggers. Within the guidance subsystem there are guidance laws determined by the inputs 1030 to be used in the simulation. These guidance laws include Acceleration Command Guidance. Acceleration Command Guidance uses a Quasi-Equilibrium Guidance (QEG) law during the glide portion of the trajectory and Proportional Navigation (ProNav) during the terminal phase of a trajectory. Both of these guidance laws output an acceleration command which is then converted to aerodynamic angle commands and fed to the autopilot.

The guidance laws can include Euler Angle Guidance.- This guidance law follows a specified pitch profile defined by the inputs 1030. It outputs a Euler angle command which is fed to the autopilot. The guidance laws can include Aerodynamic Angle Guidance, which tracks aerodynamic angles profile as defined in the inputs 1030. The guidance law will output the tracked aerodynamic angles and feed that to the autopilot.

The models 1025 can include an autopilot subsystem. The autopilot subsystem contains the control methods to take the commanded Euler angles or aerodynamic angles from the guidance subsystem and calculate the resulting throttle and angle of attack. In some cases, the autopilot system represent flight software of the vehicle being simulated.

In some cases, the first set of simulation parameters 1035 is generated by the models 1025 and readable by the simulation framework 1005. The first set of simulation parameters 1035 may not be compatible with the one or more simulators 1010.

The framework 1005 can generate a second set of parameters based on the first set of parameters and a particular simulator of the simulators. The framework can generate a second set of simulation parameters 1035 based on the first set of simulation parameters 1035 and one or more of the simulators 1010. The framework 1005 can determine that a form of the first set of simulation parameters 1035 is not compatible with a first simulator 1010A. The framework 1005 can alter, change, or otherwise modify the simulation parameters to be compatible (e.g., readable, processable) by the first simulator 1010A.

For example, a value of the first set of simulation parameters 1035 can correspond to an altitude of the vehicle. In some cases, a reference location of the altitude of the vehicle can differ from an initial reference location intrinsic to the simulator 1010. The simulation framework 1005 can replace or modify the value corresponding to the altitude to be compatible with the simulator 1010. For example, the simulation framework 1005 can remove a listener from a structure of the simulation parameters 1035. In some cases, one or more of the simulators 1010 may not allow listener objects to be within structures, and the simulation framework 1005 can remove the listener from the structure of a value of the first set of simulation parameters to generate the second set of simulation parameters. For example, the simulation framework 1005 can simplify a structure of the first set of simulation parameters 1035 with fields of different sizes if the simulator 1010 requires that all structures must have the same size.

In some cases, the simulation framework 1005 transforms a value of the simulation parameters 1035 from a first value to a second value compatible with a particular simulator 1010 upon processing of all or a subset of the models 1025. In some cases, one or more of the models 1025 perform the transformation during its operations. In some cases, one or more inputs 1030 or simulation parameters 1035 can be tagged. The tag can indicate that the model or another component of the simulation framework 1005 is to transform a value of the simulation parameters 1035 from the first value to the second value compatible with the particular simulator 1010.

The framework 1005 can provide the second set of simulation parameters 1035 to a particular simulator of the simulators 1010 according to a sequence determined by a desired output. Each output of the one or more outputs 1040 can correspond to a second set of simulation parameters 1035. For example, a first output corresponding with a first vehicle and a first perturbation corresponds to a second set of simulation parameters, and a second output corresponding with the first vehicle and a second perturbation corresponds to a different second set of simulation parameters. The framework 1005 can provide all or a subset of the second set of simulation parameters 1035 corresponding to a first output. In some cases, the framework 1005 can provide all or a subset of the second set of simulation parameters 1035 for each desired output 1040. In some cases, the desired output 1040 can determine an order and size of the simulation parameters 1035 for providing to the particular simulator 1010.

In overview, the system can accept various inputs including perturbations to provide one or more simulations. The system can identify a set of batches from the inputs. For each batch, the system can apply a model configuration, based on the various inputs and the batch. For each model configuration, the system can generate, for each of a set of repetitions defined by the perturbations, mission definitions and parameter values. The system can generate the simulation parameters 1035 corresponding to each repetition of each set. Each member of the matrix can be conditioned by the simulation framework 1005 to be compatible with a simulation program. The simulation program can provide the conditioned simulation parameters 1035 to a simulation program.

FIG. 11: illustrates a method flow of a system for flight simulations. The method 2000 can provide for initialization of the simulation framework 1005 through acceptance of inputs, operations by models, and conditioning of simulation parameters output by the models. At ACT 2005, the system can accept inputs, such as the input 1030. The inputs can include simulation data such as number of Monte Carlo reptitions (nMC), model configurations (modelConfig), mission variables (missionVars), random variables (randVars), or data dictionary variables (ddVars), size weigh power (SWP) of a vehicle, among others. One or more models of the system can generate a simulation data array (simData array). At ACT 2010, the system can determine a batch size of the simulation based on the simulation data array. The system can generate batches based on the batch size.

At ACT 2015, for each batch, the system can determine which inputs are relevant to the particular batch and curate the inputs for the particular batch. In some cases, the system can apply a model configuration from the inputs and based on the batch. In this manner, one or more simulations or repetitions of a simulation can be run without having to re-input model configurations each time.

At ACT 2020, the system can select inputs corresponding to a particular case. In some cases, a particular case can correspond to a particular perturbation, or to a particular desired outcome. The selected inputs can be considered simulation parameters. For example, one or more models can generate values of simulation parameters based on these selected inputs. The system can transform, change, or otherwise modify the simulation parameters from a first state to a second state compatible with one or more simulation softwares or further models. In some cases, these simulation parameters can be inputs to one or more further models. Further models can generate further values of simulation parameters based on the prior generated simulation parameters. For example, one or more models can generate simulation parameters based on the transformed mission variables to generate a perturbed mission variables and perturbed ddVars.

At ACT 2025, the system can generate a run for each generated perturbed simulation parameter. For example, the system can condition further simulation variables generated by the models to be compatible with a simulation software. For each run, the system can provide the conditioned simulation variables to a simulation software. Outputs are generated at ACT 2030.

### 5. IMPLEMENTATIONS

The approaches described above can be implemented, for example, using a programmable computing system executing suitable software instructions or it can be implemented in suitable hardware such as a field-programmable gate array (FPGA) or in some hybrid form. For example, in a programmed approach the software may include procedures in one or more computer programs that execute on one or more programmed or programmable computing system (which may be of various architectures such as distributed, client/server, or grid) each including at least one processor, at least one data storage system (including volatile and/or non-volatile memory and/or storage elements), at least one user interface (for receiving input using at least one input device or port, and for providing output using at least one output device or port). The software may include one or more modules of a larger program, for example, that provides services related to the design, configuration, and execution of data processing graphs. The modules of the program can be implemented as data structures or other organized data conforming to a data model stored in a data repository.

The software may be stored in non-transitory form, such as being embodied in a volatile or non-volatile storage medium, or any other non-transitory medium, using a physical property of the medium (e.g., surface pits and lands, magnetic domains, or electrical charge) for a period of time (e.g., the time between refresh periods of a dynamic memory device such as a dynamic RAM). In preparation for loading the instructions, the software may be provided on a tangible, non-transitory medium, such as a CD-ROM or other computer-readable medium (e.g., readable by a general or special purpose computing system or device), or may be delivered (e.g., encoded in a propagated signal) over a communication medium of a network to a tangible, non-transitory medium of a computing system where it is executed. Some or all of the processing may be performed on a special purpose computer, or using special-purpose hardware, such as coprocessors or field-programmable gate arrays (FPGAs), dedicated, application-specific integrated circuits (ASICs), or graphics processing units GPUs (e.g., for efficient execution of large language models or other machine learning/artificial intelligence models). The processing may be implemented in a distributed manner in which different parts of the computation specified by the software are performed by different computing elements. Each such computer program is preferably stored on or downloaded to a computer-readable storage medium (e.g., solid state memory or media, or magnetic or optical media) of a storage device accessible by a general or special purpose programmable computer, for configuring and operating the computer when the storage device medium is read by the computer to perform the processing described herein. The inventive system may also be considered to be implemented as a tangible, non-transitory medium, configured with a computer program, where the medium so configured causes a computer to operate in a specific and predefined manner to perform one or more of the processing steps described herein.

What is claimed is:

1. A system for simulation, comprising:
an input processor configured to:
receive user input specifying one or more simulation parameters in a user-specified format;
access a model-specific plugin associated with a simulation model, the plugin defining translation logic for converting simulation parameters from the user-specified format to a model-compatible format required by the simulation model; and
generate one or more simulation batches including applying the translation logic of the plugin to convert the user input into the model-compatible format; and
a simulation module configured to execute the one or more simulation batches using the simulation model to generate simulation results.

2. The system of claim 1, wherein the input processor is further configured to access a plurality of model-specific plugins, each associated with a respective simulation model, and select the plugin corresponding to a simulation model specified in the user input.

3. The system of claim 1, wherein the translation logic includes a coordinate frame transformation configured to convert one or more simulation parameters from a user-specified coordinate frame to a coordinate frame required by the simulation model.

4. The system of claim 3, wherein the coordinate frame transformation is configured to convert a user-specified position from latitude, longitude, and altitude coordinates to Earth-Centered Inertial coordinates.

5. The system of claim 3, wherein the coordinate frame transformation is configured to convert a user-specified velocity from Mach number and flight path angle to an Earth-Centered Inertial velocity vector.

6. The system of claim 1, wherein the input processor is further configured to receive a run matrix defining a plurality of cases, each case representing a variation of one or more simulation parameters, and generate a plurality of simulation batches corresponding to the cases.

7. The system of claim 6, wherein the input processor is further configured to receive sweep variables each defining a set of discrete values for a respective simulation parameter, and automatically expand the run matrix to include one case for each combination of sweep variable values.

8. The system of claim 1, wherein the batch simulation module includes a model configuration module configured to apply a model configuration once per simulation batch before iterating over any cases defined in the user input, such that a change in model configuration defines a boundary between simulation batches.

9. The system of claim 1, wherein the batch simulation module further includes a repetition module configured to execute the simulation model for each of a plurality of repetitions defined by a Monte Carlo configuration specified in the user input, each repetition applying a random perturbation to one or more simulation parameters.

10. The system of claim 9, wherein the input processor is further configured to apply the random perturbations to user-specified values before applying a coordinate frame transformation defined by the plugin, such that the perturbations are applied in the user-specified coordinate frame.

11. The system of claim 9, wherein the batch simulation module further comprises a matrix repetition module configured to iterate over a plurality of run matrix cases, and wherein the repetition module is nested within the matrix repetition module such that each run matrix case is executed for a full number of repetitions before a next run matrix case begins.

12. The system of claim 1, wherein the batch simulation module further comprises a simulation instantiation module configured to instantiate a plurality of simulation runs for parallel execution.

13. The system of claim 12, wherein the batch simulation module is further configured to clear simulation data from memory after completing a simulation batch and before beginning a subsequent simulation batch.

14. The system of claim 1, wherein the input processor is further configured to form a simulation data object including the user input and the model-compatible format parameters that is passed through an execution pipeline of the system.

15. The system of claim 1, wherein the batch simulation module is further configured to receive one or more stop conditions each defining at least one of an upper bound or a lower bound on a monitored simulation quantity, and terminate a simulation run when the monitored quantity satisfies the stop condition.

16. The system of claim 1, further comprising a user interface configured to receive the user input and produce a configuration file, wherein the input processor is configured to read the configuration file to generate the one or more simulation batches.

17. The system of claim 1, further comprising an output processor configured to aggregate simulation outputs across a plurality of simulation runs and compute one or more measures of effectiveness from the aggregated outputs.

18. The system of claim 1, wherein the batch simulation module is further configured to select a vehicle dynamics model at a fidelity level specified in the user input, the fidelity level selected from a plurality of fidelity levels including at least a three-degrees-of-freedom model and a six-degrees-of-freedom model.

19. A method for simulation, comprising:
receiving user input specifying one or more simulation parameters in a user-specified format;
accessing a model-specific plugin defining translation logic for converting the simulation parameters to a model-compatible format required by a simulation model;
generating one or more simulation batches including applying the translation logic to convert the user input into the model-compatible format; and
executing the one or more simulation batches using the simulation model to generate simulation results.

20. A non-transitory computer-readable medium storing instructions that, when executed by one or more processors, cause the processors to:
receive user input specifying one or more simulation parameters in a user-specified format;
access a model-specific plugin defining translation logic for converting the simulation parameters to a model-compatible format required by a simulation model;
generate one or more simulation batches including applying the translation logic to convert the user input into the model-compatible format; and
execute the one or more simulation batches using the simulation model to generate simulation results.
